(19) United States
(12) Patent Application Publication
(10) Pub. No.: US 2025/0096054 A1
(43) Pub. Date: Mar. 20, 2025

(54) WIRING SUBSTRATE, COMPOSITE SUBSTRATE, AND MANUFACTURING METHOD OF WIRING SUBSTRATE

(71) Applicant: NICHIA CORPORATION, Anan-shi (JP)

(72) Inventors: Eiko MINATO, Anan-shi (JP); Atsushi HOSOKAWA, Tokushima-shi (JP); Akiko NAGAE, Tokushima-shi (JP); Takashi KAWAMATA, Tokushima-shi (JP)

(73) Assignee: NICHIA CORPORATION, Anan-shi (JP)

(21) Appl. No.: 18/830,590

(22) Filed: Sep. 11, 2024

(30) Foreign Application Priority Data
Sep. 19, 2023 (JP) 2023-151531

(51) Int. Cl. H01L 23/15; C04B 41/00; C04B 41/45; C04B 41/51; C04B 41/52; C04B 41/88; C04B 41/90; H01L 21/48; H01L 23/00; H01L 23/498

(52) U.S. Cl. CPC H01L 23/15; C04B 41/0072; C04B 41/009; C04B 41/4539; C04B 41/4576; C04B 41/51; C04B 41/52; C04B 41/88; C04B 41/90; H01L 21/4867; H01L 23/49838; H01L 24/16; H01L 2224/16227

(57) ABSTRACT

A wiring substrate includes a ceramic substrate having an upper surface, a lower surface, and a lateral surface. The lower surface includes a first lower surface and a second lower surface inward from the first lower surface. The lateral surface includes a first lateral surface and a second lateral surface inward from the first lateral surface. The wiring substrate includes a first wiring having a thickness of 80% or more of a height from the second lower surface to the first lower surface and disposed in contact with the second lower surface and the second lateral surface. A lateral surface of the first wiring is exposed from the first lateral surface. A main surface of 50% or more of a surface area of a lower surface of the first wiring is substantially parallel to the second lower surface and is disposed inward from the first lower surface.

### CROSS-REFERENCE TO RELATED APPLICATIONS

The present application claims priority under 35 U.S.C. § 119 to Japanese Patent Application No. 2023-151531, filed Sep. 19, 2023, the contents of which is hereby incorporated by reference in its entirety.

### BACKGROUND

### 1. Technical Field

The present disclosure relates to a wiring substrate, a composite substrate, and a manufacturing method of the wiring substrate.

### 2. Description of Related Art

As a wiring substrate, a wiring substrate including a conductive pattern formed inside a ceramic substrate and on a surface thereof by using a conductive material such as a metal is known. Such a wiring substrate is connected to other components by solder or the like. For example, see Japanese Patent Publication No. 2022-106325.

### SUMMARY OF THE INVENTION

Embodiments of the present disclosure provide a wiring substrate having high thermal conductivity with another component when the wiring substrate is connected to the another component, and a manufacturing method of the wiring substrate.

A first aspect of the present disclosure is a wiring substrate including a ceramic substrate having an upper surface, a lower surface opposite to the upper surface, and a lateral surface between the upper surface and the lower surface, the lower surface including a first lower surface located on a first outermost side of the ceramic substrate and a second lower surface located inward from the first lower surface, the lateral surface including a first lateral surface located on a second outermost side of the ceramic substrate and a second lateral surface located inward from the first lateral surface; and a first wiring having a thickness of 80% or more of a height from the second lower surface to the first lower surface, the first wiring being disposed in contact with the second lower surface and the second lateral surface, in which a lateral surface of the first wiring is exposed from the first lateral surface of the ceramic substrate, and a main surface of a lower surface of the first wiring is substantially parallel to the second lower surface, the main surface being disposed inward from the first lower surface, the main surface being 50% or more of a surface area of the lower surface of the first wiring.

A second aspect of the present disclosure is a composite substrate including the wiring substrate, a first component, and a connection member that electrically connects the first wiring of the wiring substrate and the first component.

A third aspect of the present disclosure is a manufacturing method of a wiring substrate including preparing a ceramic substrate including an upper surface, a lower surface opposite to the upper surface, and a lateral surface between the upper surface and the lower surface, the lower surface including a first lower surface located on a first outermost side of the ceramic substrate and a second lower surface located inward from the first lower surface, the lateral surface including a first lateral surface located on a second outermost side of the ceramic substrate and a second lateral surface located inward from the first lateral surface; forming a first conductive paste layer by disposing a first conductive paste on the second lower surface; forming a first wiring intermediate by firing the first conductive paste layer; and forming a first wiring such that a main surface of a lower surface of the first wiring is substantially parallel to the second lower surface, the main surface being 50% or more of a surface area of the lower surface of the first wiring, the first wiring being disposed inward from the first lower surface, by polishing or grinding the first wiring intermediate. In the forming of the first wiring, the first wiring has a thickness of 80% or more of a height from the second lower surface to the first lower surface, the first wiring being disposed in contact with the second lower surface and the second lateral surface, and a lateral surface of the first wiring is exposed from the first lateral surface of the ceramic substrate.

One aspect of the present disclosure can provide a wiring substrate having high thermal conductivity with another component when the wiring substrate is connected to the another component, and a manufacturing method of the wiring substrate.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic bottom view illustrating a wiring substrate according to a first embodiment.

FIG. 2 is a schematic plan view illustrating the wiring substrate according to the first embodiment.

FIG. 3 is a schematic cross-sectional view illustrating a cross section taken along line III-III in FIG. 1.

FIG. 4 is a schematic enlarged view of a part of FIG. 3.

FIG. 5A is a schematic cross-sectional view illustrating a prepared ceramic substrate in a manufacturing method of the wiring substrate according to the first embodiment.

FIG. 5B is a schematic cross-sectional view illustrating a state in which a first conductive paste layer and a second conductive paste layer are disposed in the manufacturing method of the wiring substrate according to the first embodiment.

FIG. 5C is a schematic cross-sectional view illustrating a state in which a first wiring intermediate and a second wiring intermediate are formed in the manufacturing method of the wiring substrate according to the first embodiment.

FIG. 5D is a schematic cross-sectional view illustrating a state in which a first wiring and a second wiring are formed in the manufacturing method of the wiring substrate according to the first embodiment.

FIG. 5E is a schematic cross-sectional view illustrating a state in which a first metal layer and a second metal layer are formed in the manufacturing method of the wiring substrate according to the first embodiment.

FIG. 6 is a schematic bottom view illustrating a wiring substrate according to a second embodiment.

FIG. 7 is a schematic cross-sectional view illustrating a cross section taken along line VII-VII in FIG. 6.

FIG. 8 is a schematic bottom view illustrating a wiring substrate according to a third embodiment.

FIG. 9 is a schematic cross-sectional view illustrating a cross section taken along line IX-IX in FIG. 8.

FIG. 10 is a schematic bottom view illustrating a wiring substrate according to a fourth embodiment.

FIG. 11A is a schematic bottom view illustrating a prepared ceramic substrate in a manufacturing method of the wiring substrate according to the fourth embodiment.

FIG. 11B is a schematic cross-sectional view illustrating a cross section taken along line XIB-XIB in FIG. 11A.

FIG. 11C is a schematic cross-sectional view illustrating a cross section taken along line XIC-XIC in FIG. 11A.

FIG. 12 is a schematic cross-sectional view illustrating a wiring substrate according to a first modified example.

FIG. 13 is a schematic cross-sectional view illustrating a composite substrate according to a fifth embodiment.

FIG. 14 is a schematic cross-sectional view illustrating a composite substrate according to a sixth embodiment.

### DETAILED DESCRIPTION

### Description of Embodiments

Embodiments according to the present disclosure are described below with reference to the drawings. However, the embodiments described below are merely intended to embody the technical concept according to the present disclosure, and the invention is not limited to the following description unless otherwise specified. The content described in one embodiment can also be applied to another embodiment or a modified example. The drawings schematically illustrate embodiments, and in order to clarify the description, scales, intervals, positional relationships, and the like of the members may be exaggerated, illustration of part of the members may be omitted, or an end view illustrating only a cut surface may be used as a cross-sectional view. Directions illustrated in the drawings indicate relative positions between constitution components and are not intended to indicate absolute positions. Members having the same names and reference characters, as a rule, represent the same members or members of the same quality, and detailed description thereof is omitted as appropriate.

### First Embodiment

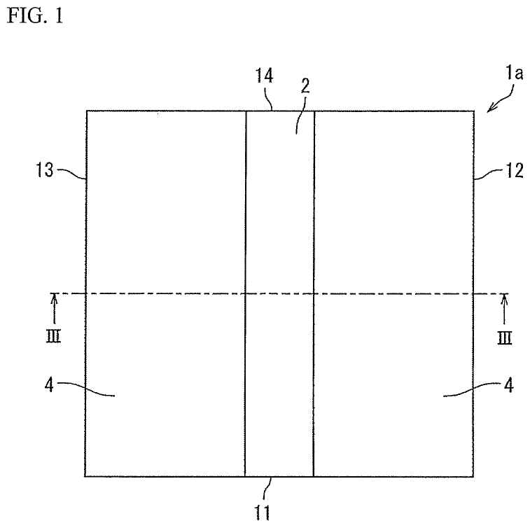

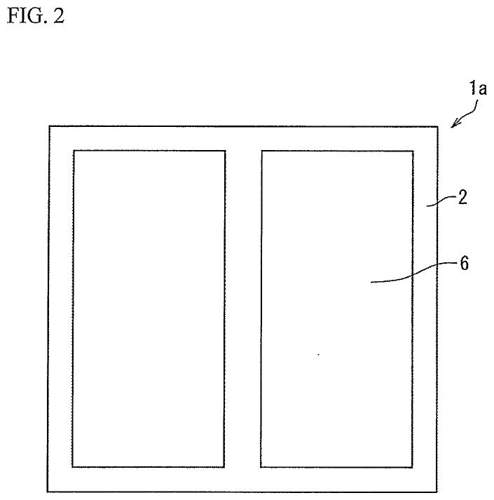

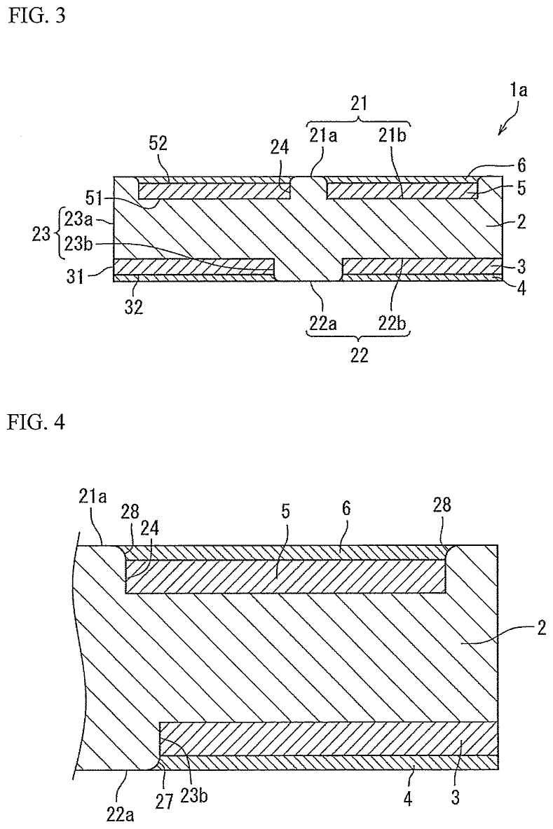

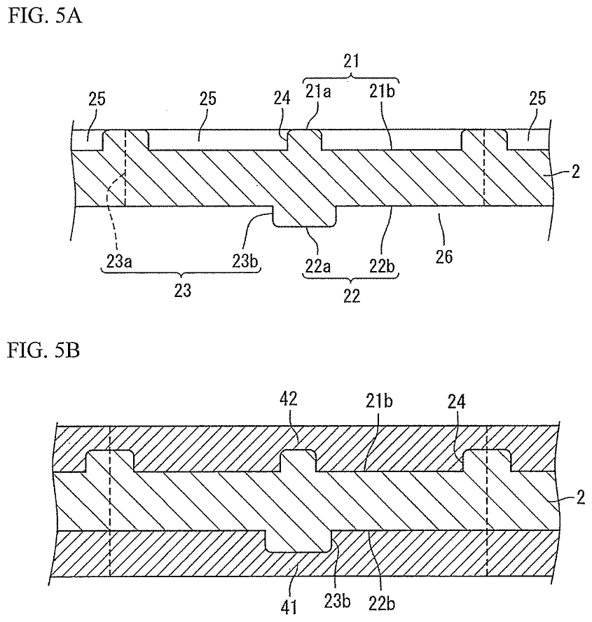

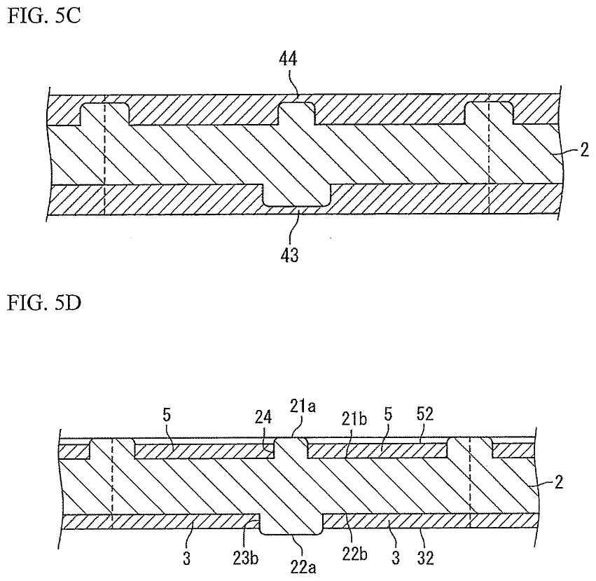

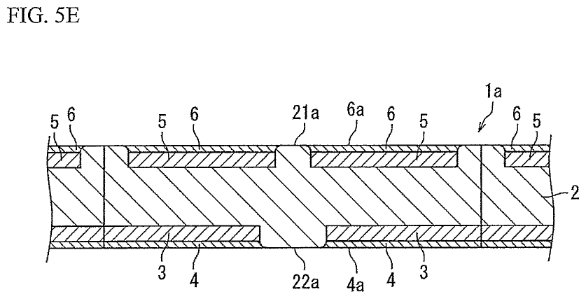

A wiring substrate 1a and a manufacturing method of the wiring substrate 1a according to a first embodiment are described with reference to FIGS. 1 to 4 and FIGS. 5A to 5E. FIG. 1 is a schematic bottom view illustrating the wiring substrate 1a. FIG. 2 is a schematic plan view illustrating the wiring substrate 1a. FIG. 3 is a schematic cross-sectional view illustrating a cross section taken along line III-III in FIG. 1. FIG. 4 is a schematic enlarged view of a portion where a first wiring 3 and a second wiring 5 in FIG. 3 are located. FIGS. 5A to 5E are schematic cross-sectional views for explaining a manufacturing method of the wiring substrate 1a illustrated in FIGS. 1 to 4. Note that dotted lines in FIGS. 5A to 5E indicate portions to be cut of a ceramic substrate.

The wiring substrate 1a of the first embodiment according to the present disclosure includes a ceramic substrate 2 having an upper surface 21, a lower surface 22 opposite to the upper surface 21, and a lateral surface 23 between the upper surface 21 and the lower surface 22, the lower surface 22 having a first lower surface 22a located on the outermost side and a second lower surface 22b located inward from the first lower surface 22a, the lateral surface 23 having a first lateral surface 23a located on the outermost side and a second lateral surface 23b located on the innermost side on the lower surface 22 side; and a first wiring 3 having a thickness of 80% or more of a height from the second lower surface 22b to the first lower surface 22a and disposed in contact with the second lower surface 22b and the second lateral surface 23b. A lateral surface 31 of the first wiring 3 is exposed from the first lateral surface 23a of the ceramic substrate 2, and a main surface of 50% or more of a surface area of a lower surface 32 of the first wiring 3 is substantially parallel to the second lower surface 22b and is disposed inward from the first lower surface 22a. The wiring substrate 1a has a rectangular shape in top view, lateral surfaces of the wiring substrate 1a include a front surface 11, a right lateral surface 12 and a left lateral surface 13 adjacent to the front surface 11, and a back surface 14 opposite to the front surface 11 and adjacent to the right lateral surface 12 and the left lateral surface 13, and the first wiring 3 is present on the front surface 11, the right lateral surface 12, the left lateral surface 13, and the back surface 14. The upper surface 21 includes a first upper surface 21a located on the outermost side and a second upper surface 21b located inward from the first upper surface 21a. The ceramic substrate 2 has a recessed portion 25 defined by the second upper surface 21b and a fifth lateral surface 24 between the first upper surface 21a and the second upper surface 21b. The wiring substrate 1a includes a second wiring 5 in the recessed portion 25. The second wiring 5 has a thickness of 80% or more of the height from the second upper surface 21b to the first upper surface 21a of the ceramic substrate 2, and is disposed in contact with the second upper surface 21b. The main surface of 50% or more of the surface area of an upper surface 52 of the second wiring 5 is substantially parallel to the second upper surface 21b and is disposed inward from the first upper surface 21a. The wiring substrate 1a includes a first metal layer 4 disposed on the lower surface 32 of the first wiring 3. The wiring substrate 1a includes a second metal layer 6 disposed on the upper surface 52 of the second wiring 5. As illustrated in FIG. 4, in cross-sectional view in a thickness direction of the ceramic substrate 2, a first corner portion 27 defined by the first lower surface 22a and the second lateral surface 23b is rounded, and the first metal layer 4 covers the first corner portion 27. A second corner portion 28 defined by the first upper surface 21a and the fifth lateral surface 24 is rounded, and the second metal layer 6 covers the second corner portion 28.

### Manufacturing Method of Wiring Substrate

A manufacturing method of the wiring substrate 1a of the first embodiment according to the present disclosure includes (a) preparing the ceramic substrate 2 including the upper surface 21, the lower surface 22 opposite to the upper surface 21, and the lateral surface 23 between the upper surface 21 and the lower surface 22, the lower surface 22 having the first lower surface 22a located on the outermost side and the second lower surface 22b located inward from the first lower surface 22a, the lateral surface 23 having the first lateral surface 23a located on the outermost side and the second lateral surface 23b located on the innermost side on the lower surface 22 side; (b) forming a first conductive paste layer 41 by disposing a first conductive paste on the second lower surface 22b; (c) forming a first wiring intermediate 43 by firing the first conductive paste layer 41; and (d) forming the first wiring 3 such that the main surface of 50% or more of the surface area of the lower surface 32 of the first wiring 3 is substantially parallel to the second lower surface 22b and the first wiring 3 is disposed inward from the first lower surface 22a, by polishing or grinding the first wiring intermediate 43, and in (b) forming the first wiring 3, the first wiring 3 has a thickness of 80% or more of a height from the second lower surface 22b to the first lower surface 22a and is disposed in contact with the second lower surface 22b and the second lateral surface 23b and the lateral surface 31 of the first wiring 3 is exposed from the first lateral surface 23a of the ceramic substrate 2.

Preferably, the manufacturing method of the wiring substrate 1a of the first embodiment according to the present disclosure further includes, in the preparing of the ceramic substrate 2, preparing the ceramic substrate 2 provided, on the upper surface 21 thereof, with the first upper surface 21a and the second upper surface 21b located inward from the first upper surface 21a. Preferably, the manufacturing method of the wiring substrate 1a further includes disposing a second conductive paste on the second upper surface 21b to form a second conductive paste layer 42 after preparing the ceramic substrate 2, and firing the second conductive paste layer 42 to form a second wiring intermediate 44 in the forming of the first wiring intermediate 43. In the manufacturing method of the wiring substrate of the present disclosure, these steps can be omitted. That is, the wiring substrate of the present disclosure need not include the second upper surface 21b and the second wiring 5. In other words, the upper surface 21 of the ceramic substrate 2 may be only the first upper surface 21a.

Preferably, the manufacturing method of the wiring substrate 1a of the first embodiment according to the present disclosure further includes (e) forming the first metal layer 4 on the lower surface 32 of the first wiring 3. Preferably, the manufacturing method of the wiring substrate 1a of the first embodiment according to the present disclosure further includes forming the second metal layer 6 on the upper surface 52 of the second wiring 5.

The steps are described in detail below.

### (a) Preparing Ceramic Substrate

The ceramic substrate 2 is provided (FIG. 5A).

The ceramic substrate 2 is an insulating member serving as a base that is provided with the first wiring 3 and the second wiring 5 later. The ceramic substrate 2 has the upper surface 21, the lower surface 22 opposite to the upper surface 21, and the lateral surface 23 between the upper surface 21 and the lower surface 22. The lower surface 22 includes the first lower surface 22a located on the outermost side and the second lower surface 22b located inward from the first lower surface 22a. The lateral surface 23 includes the first lateral surface 23a located on the outermost side and the second lateral surface 23b located on the innermost side on the lower surface 22 side. The second lower surface 22b and the second lateral surface 23b define a first arrangement portion 26. The first wiring 3 is disposed in the first arrangement portion 26. The upper surface 21 includes the first upper surface 21a located on the outermost side and the second upper surface 21b located inward from the first upper surface 21a. The ceramic substrate 2 includes the recessed portion 25 defined by the second upper surface 21b and the fifth lateral surface 24 between the first upper surface 21a and the second upper surface 21b. Although one ceramic substrate 2 is illustrated, an assembly substrate including a plurality of ceramic substrates 2 aligned in a row direction and a column direction can be used.

The material of the ceramic substrate 2 is preferably a ceramic having high thermal conductivity from the viewpoint of heat dissipation. For example, the material of the ceramic substrate 2 is preferably a nitride ceramic such as silicon nitride, aluminum nitride, or boron nitride, but can be an oxide ceramic such as aluminum oxide, silicon oxide, calcium oxide, or magnesium oxide.

The thickness of the ceramic substrate 2 is preferably, for example, in a range from 0.08 mm to 2 mm. The thickness of the ceramic substrate 2 means a distance between the first upper surface 21a and the first lower surface 22a.

The first arrangement portion 26 has a rectangular shape in plan view, and has a long direction and a short direction. Two first arrangement portions 26 are arranged such that long sides thereof face each other.

The recessed portion 25 has a rectangular shape in plan view, and has a long direction and a short direction. Two recessed portions 25 are arranged such that long sides thereof face each other.

As illustrated in FIG. 4, in cross-sectional view in the thickness direction of the ceramic substrate 2, the first corner portion 27 defined by the first lower surface 22a and the second lateral surface 23b is rounded. In cross-sectional view in the thickness direction of the ceramic substrate 2, the second corner portion 28 defined by the first upper surface 21a and the fifth lateral surface 24 is rounded. Since the first corner portion 27 and the second corner portion 28 are rounded, a contact area between the ceramic substrate 2 and the first metal layer 4 and a contact area between the ceramic substrate 2 and the second metal layer 6 are increased, so that the adhesion is improved. In addition, since a distance from the first lower surface 22a to the first wiring 3 and a distance from the first upper surface 21a to the second wiring 5 are increased, the length of a portion where the ceramic substrate 2 is in contact with the first metal layer 4 and the second metal layer 6 in cross-sectional view is increased. That is, an entry path of substances from an external environment, such as oxygen, sulfur, and moisture, becomes longer. Accordingly, substances entering from the external environment are less likely to reach the first wiring 3 and the second wiring 5, so that deterioration of the first wiring 3 and the second wiring 5 can be suppressed. Typically, sulfurization of the first wiring 3 and the second wiring 5 is suppressed.

Inner surfaces defining the first arrangement portion 26 and the recessed portion 25, that is, the second lower surface 22b, the second lateral surface 23b, the second upper surface 21b, and the fifth lateral surface 24 are preferably roughened. The roughening can reduce peeling of the first wiring 3 and the second wiring 5 disposed in the first arrangement portion 26 and the recessed portion 25. An arithmetic mean roughness Ra of the inner surface defining the first arrangement portion 26 and the recessed portion 25 can be, for example, in a range from 200 nm to 2 μm, and is preferably in a range from 300 nm to 800 nm. The arithmetic mean roughness Ra can be measured in accordance with JIS B 0601 using a stylus type surface roughness measuring instrument (for example, SE 3500 manufactured by Kosaka Laboratory Ltd.) equipped with a diamond stylus having a tip radius r of curvature of 2 μm.

The ceramic substrate 2 is a fired substrate. When a green sheet before firing is used and a conductive paste is disposed, warpage or shrinkage of the green sheet increases, making it difficult to dispose the first wiring 3 and the second wiring 5 with high accuracy. In contrast, in the present embodiment, since a fired ceramic substrate is used and a conductive paste is disposed, warpage and shrinkage are significantly reduced, making it possible to dispose the first wiring 3 and the second wiring 5 with high accuracy.

The ceramic substrate 2 can be molded by firing a ceramic, or a fired substrate such as a commercially available product can be used. The first arrangement portion 26 and the recessed portion 25 in the ceramic substrate 2 can be provided in advance, or can be formed after purchasing a fired substrate such as a commercially available product. Alternatively, a substrate provided with the first arrangement portion 26 and the recessed portion 25 can be purchased as the ceramic substrate 2.

The first arrangement portion 26 and the recessed portion 25 can be formed, for example, by etching, blasting, or laser processing; however, laser processing is preferably employed because the laser processing can form the recessed portion 25 with high accuracy. Only one of etching, blasting, and laser processing can be performed, or two or more of these can be combined. During such processing, the first corner portion 27 and the second corner portion 28 can be rounded.

As the etching, wet etching or dry etching can be performed, and the wet etching is preferable. In the wet etching, etching is performed using an acidic or alkaline chemical such as HF, NH₄F, KOH, NaOH, or CsOH, whereby the first arrangement portion 26 having a curved shape can be formed.

In the blasting, abrasive grains are caused to collide with the upper surface 21 or the lower surface 22 from a perpendicular direction, so that the ceramic substrate 2 is polished or ground to have a desired shape.

Before the etching or blasting, a resist having a predetermined pattern can be disposed. For example, the resist is formed as follows.

A dry film is bonded to the upper surface 21 or the lower surface 22 of the ceramic substrate 2. The dry film is a sheet-like photoresist. For example, the dry film in which the exposed region is to be cured is used.

Subsequently, the dry film is exposed and developed. Before the exposure, a mask is attached to the dry film in an overlapping manner. The mask has a light-shielding pattern in a region for forming the first arrangement portion 26 and the recessed portion 25. Subsequently, light is emitted to perform exposure. The light is, for example, ultraviolet light. A region other than the light-shielding pattern transmits the light, and the dry film at the position of the region is cured. In the subsequent development, the mask is removed, and an uncured portion of the dry film is dissolved and removed with an alkaline aqueous solution or the like. The cured portion is not dissolved and not removed but remains, and a resist is formed.

The resist is removed after the etching or blasting.

For example, the preparing of the ceramic substrate can include disposing a photoresist on the upper surface 21 and/or the lower surface 22 of the ceramic substrate 2, performing exposure and development on the photoresist through a mask, etching or blasting the ceramic substrate 2 through the photoresist formed in a predetermined pattern by performing the exposure and the development, forming the first arrangement portion 26 and/or the recessed portion 25 by the etching or blasting, and removing the photoresist from the ceramic substrate 2. Alternatively, the first arrangement portion 26 and/or the recessed portion 25 can be formed by preparing a ceramic substrate and directly irradiating the substrate with a laser without using a photoresist.

### (b) Forming Conductive Paste Layer

The first conductive paste is disposed on the second lower surface 22b to form the first conductive paste layer 41. In the first embodiment, the second conductive paste is disposed on the second upper surface 21b to form the second conductive paste layer 42 (FIG. 5B). The first conductive paste and the second conductive paste may be collectively referred to as a conductive paste. The first conductive paste layer and the second conductive paste layer may also be collectively referred to as a conductive paste layer.

The first conductive paste is disposed in the first arrangement portion 26 of the ceramic substrate 2 to form the first conductive paste layer 41. The first conductive paste layer 41 becomes the first wiring 3 by firing. The first conductive paste is a member having fluidity, and can be disposed by being applied in close contact with the second lower surface 22b and the second lateral surface 23b. Likewise, the second conductive paste is disposed in the recessed portion 25 of the ceramic substrate 2 to form the second conductive paste layer 42. The second conductive paste layer 42 becomes the second wiring 5 by firing. The conductive paste can be disposed by being applied in close contact with the second upper surface 21b and the fifth lateral surface 24. The first arrangement portion 26 and the recessed portion 25 are filled with the conductive paste up to a position higher than the first lower surface 22a and the first upper surface 21a. The present disclosure is not limited to such an aspect, and for example, the conductive paste can be disposed up to the same position as those of the first lower surface 22a and the first upper surface 21a, or up to a position lower than those of the first lower surface 22a and the first upper surface 21a. In this case, the second wiring intermediate can be used as the second wiring 5 as is.

The conductive paste contains a first metal powder. The first metal powder can contain at least one selected from Ag, Cu, Al, Zn, Sn, Ni, and an Ag—Cu alloy. Among them, an Ag—Cu alloy that can be fired at a relatively low temperature in a range from 780° C. to 950° C. is preferable. The first metal powder can also contain Cu, Ag, or the like together with an Ag—Cu alloy having high electrical conductivity. This is because firing can be performed at a temperature lower than the melting points of Ag and Cu, and a wiring having a thermal conductivity close to that of Ag 100% or Cu 100% can be formed. When the conductive paste containing the first metal powder is disposed in the first arrangement portion 26 or the recessed portion 25, the size of the first metal powder is smaller than the depth of the first arrangement portion 26 or the recessed portion 25. For example, a median diameter of the first metal powder is preferably in a range from 0.5 μm to 50 μm, more preferably in a range from 0.8 μm to 20 μm, particularly preferably in a range from 1 μm to 3 m. When the median diameter of the first metal powder is 1 μm or more, aggregation can be suppressed and thermal conductivity can be increased. On the other hand, when the median diameter of the first metal powder is 3 μm or less, the filling property can be enhanced. The shape of the first metal powder is preferably spherical or ellipsoidal from the viewpoint of fluidity, but can be flat or needle-like. This is because the contact between particles can be increased, thermal conductivity can be increased, and the electrical resistance can be decreased by forming the first metal powder into a flat shape or a needle shape.

The conductive paste can contain at least an active metal powder. The active metal powder can be at least one selected from TiH₂, CeH₂, ZrH₂, and MgH₂. Among them, TiH₂ is preferable. By containing TiH₂, the conductive paste reacts with nitrogen contained in the ceramic substrate 2 and a metal compound layer is formed as a reaction layer of TiN or the like at an interface with the ceramic substrate 2. This improves the adhesion between the ceramic substrate 2 and each of the first wiring 3 and the second wiring 5 obtained by curing the conductive paste.

The conductive paste can further contain a first organic solvent. Examples of the first organic solvent include those used in general conductive pastes. Examples of the first organic solvent include glycol-based solvents, carbitol-based solvents, and terpineol-based solvents.

The conductive paste can further contain a first organic resin binder. The viscosity of the conductive paste can be adjusted depending on the type and amount of the first organic resin binder. The first organic resin binder can be, for example, a solvent generally used as a conductive paste or a resin material such as acrylic, epoxy, urethane, ethyl cellulose, silicone, phenol, polyimide, polyurethane, melamine, or urea. The first organic resin binder is decomposed by firing to be described below, evaporated, and removed.

The conductive paste can contain a plurality of inorganic fillers other than metals. By containing the inorganic fillers, volume shrinkage during sintering of the conductive paste can be reduced. Examples of the inorganic fillers that can be used include AlN and Si₃N₄.

The first conductive paste and the second conductive paste can be the same as each other or different from each other. The first conductive paste and the second conductive paste are preferably the same as each other.

### (c) Forming Wiring Intermediate by Firing Conductive Paste Layer

The first conductive paste layer 41 is fired to form the first wiring intermediate 43. In the present first embodiment, the second conductive paste layer 42 is fired at the same time to form the second wiring intermediate 44 (FIG. 5C).

The firing temperature when the conductive paste layer is fired can be in a range from 700° C. to 1200° C., and is preferably in a range from 750° C. to 1100° C., more preferably in a range from 780° C. to 950° C., particularly preferably in a range from 780° C. to 850° C. The firing atmosphere is preferably a vacuum atmosphere of 10⁻³ Pa or less or an Ar atmosphere of 99.9% or more.

Note that the wiring intermediate can be formed by a method other than forming and firing a conductive paste layer. For another method, a plating seed layer can be formed on both surfaces of a ceramic substrate including the first arrangement portion 26 and/or the recessed portion 25 by sputtering or the like, and then a wiring intermediate can be formed by electrolytic plating, for example, electrolytic copper plating.

### (d) Forming Wiring by Polishing or Grinding Wiring Intermediate

The first wiring intermediate 43 is polished or ground to form the first wiring 3 such that the main surface of 50% or more of the surface area of the lower surface 32 of the first wiring 3 is substantially parallel to the second lower surface 22b and is disposed inward from the first lower surface 22a. The formed first wiring 3 and the first lower surface 22a are preferably spaced apart from each other. In the present first embodiment, the second wiring intermediate 44 is polished or ground to form the second wiring 5 such that the main surface of 50% or more of the surface area of the upper surface 52 of the second wiring 5 is substantially parallel to the second upper surface 21b and is disposed inward from the first upper surface 21a (FIG. 5D). The formed second wiring 5 and the first upper surface 21a are preferably spaced apart from each other.

The first wiring intermediate 43 is polished and ground such that the main surface of 50% or more, preferably 80% or more, more preferably 90% or more, even more preferably 95% or more of the surface area of the lower surface 32 of the first wiring 3 is substantially parallel to the second lower surface 22b. The first wiring 3 can be located at a position higher than the main surface in a portion in contact with the second lateral surface 23b. That is, the first wiring 3 can be located closer to the first lower surface 22a side relative to the main surface in the portion in contact with the second lateral surface 23b. For example, the first wiring 3 can be at the same height as the first lower surface 22a at the boundary portion with the first lower surface 22a. The term “substantially parallel” can include not only a case of being strictly parallel but also a case in which a deviation from the parallel is 5° or less (typically 3° or less). The first wiring intermediate 43 is polished and ground such that the first wiring 3 is disposed inward from the first lower surface 22a. The expression “the first wiring 3 is disposed inward from the first lower surface 22a” means that the main surface of the first wiring 3 is located inward from the first lower surface 22a. For example, the boundary portion between the first wiring 3 and the first lower surface 22a can be at the same height as the first lower surface 22a, and the other portion can be located inward from the first lower surface 22a. Preferably, the polishing and grinding are performed such that the first wiring 3 and the first lower surface 22a are spaced apart from each other. As described above, substances entering from the external environment, such as oxygen, sulfur, and moisture, are less likely to reach the first wiring 3, so that deterioration of the first wiring 3 can be suppressed.

The second wiring intermediate 44 is polished and ground such that the main surface of 50% or more, preferably 80% or more, more preferably 90% or more, even more preferably 95% or more of the surface area of the upper surface 52 of the second wiring 5 is substantially parallel to the second upper surface 21b. The second wiring 5 can be located at a position higher than the main surface in a portion in contact with the fifth lateral surface 24. That is, the second wiring 5 can be located closer to the first upper surface 21a side relative to the main surface in the portion in contact with the fifth lateral surface 24. For example, the second wiring 5 can be at the same height as the first upper surface 21a at the boundary portion with the first upper surface 21a. The second wiring intermediate 44 is polished and ground such that the second wiring 5 is disposed inward from the first upper surface 21a. The expression “the second wiring 5 is disposed inward from the first upper surface 21a” means that the main surface of the second wiring 5 is located inward from the first upper surface 21a. For example, the boundary portion between the second wiring 5 and the first upper surface 21a can be at the same height as the first upper surface 21a, and the other portion can be located inward from the first upper surface 21a. Preferably, the polishing and grinding are performed such that the second wiring 5 and the first upper surface 21a are spaced apart from each other.

The above polishing or grinding can be performed by, for example, polishing with abrasive grains or grinding using a grindstone in which diamond is embedded.

In forming the first wiring, the first wiring intermediate is preferably polished or ground such that the main surface of the lower surface 32 of the first wiring 3 is located at least 0.4 μm or more, for example, 0.6 μm or more, 0.8 μm or more, or 1.0 μm or more inward from the first lower surface 22a. The main surface of the lower surface 32 of the first wiring 3 is located preferably within 5.0 μm, for example, within 3.0 μm, within 2.0 μm, or within 1.5 μm from the first lower surface 22a.

In forming the second wiring, the second wiring intermediate is preferably polished or ground such that the main surface of the upper surface 52 of the second wiring 5 is located at least 0.4 μm or more, for example, 0.6 μm or more, 0.8 μm or more, or 1.0 m or more inward from the first upper surface 21a. The main surface of the upper surface 52 of the second wiring 5 is located preferably within 5.0 μm, for example, within 3.0 μm, within 2.0 μm, or within 1.5 μm from the first upper surface 21a.

In the wiring substrate of the present disclosure, the subsequent step (e) need not be performed, and the first wiring intermediate and the second wiring intermediate can be used as the first wiring and the second wiring, respectively.

### (e) Forming Metal Layer on Wiring

After the first wiring 3 is formed, the first metal layer 4 is further formed on the lower surface 32 of the first wiring 3. In forming the first metal layer 4, the first metal layer 4 is formed such that a surface 4a of the first metal layer 4 and the first lower surface 22a are flush with each other or the surface 4a of the first metal layer 4 protrudes from the first lower surface 22a. The height of the protrusion from the first lower surface 22a is preferably 3 μm or less. After the second wiring 5 is formed, the second metal layer 6 is further formed on the upper surface 52 of the second wiring 5. In forming the second metal layer 6, the second metal layer 6 is formed such that a surface 6a of the second metal layer 6 and the first upper surface 21a are flush with each other or the surface 6a of the second metal layer 6 protrudes from the first upper surface 21a (FIG. 5E). The height of the protrusion from the first upper surface 21a is preferably 3 μm or less. The first metal layer 4 and the second metal layer 6 can be collectively referred to as a metal layer. The surface 4a of the first metal layer 4 and the first lower surface 22a being flush with each other means that the main surface of the surface 4a of the first metal layer 4 and the first lower surface 22a are flush with each other. For example, an edge portion of the first metal layer 4 can be located outward from the first lower surface 22a as long as the main surface of the surface 4a of the first metal layer 4 and the first lower surface 22a are flush with each other. The same applies to the surface 6a of the second metal layer 6 and the first upper surface 21a.

The metal layer can contain, for example, at least one selected from gold, platinum, palladium, rhodium, nickel, tungsten, molybdenum, chromium, and titanium. The metal layer can be a single layer or a multilayer. The metal layer can be formed by, for example, plating (electrolytic plating or electroless plating), vapor deposition, sputtering, or the like. At least one of the first metal layer 4 and the second metal layer 6 is preferably formed by plating. Both the first metal layer 4 and the second metal layer 6 are particularly preferably formed by plating. The metal layer can also be formed through a mask. The first metal layer 4 and the second metal layer 6 can have the same configuration or different configurations. For example, the first metal layer 4 and the second metal layer 6 can contain the same metal or can contain different metals. The first metal layer 4 and the second metal layer 6 can also have the same layer configuration or can have different layer configurations.

In forming the first metal layer 4 and the second metal layer 6, an edge portion of at least one of the first metal layer 4 and the second metal layer 6 is preferably pressed. That is, at least one of the first metal layer 4 and the second metal layer 6 in the boundary portion with the ceramic substrate 2 is preferably pressed inward in the thickness direction of the ceramic substrate 2. The edge portion of at least one of the first metal layer 4 and the second metal layer 6 is formed in a state of floating from the ceramic substrate 2, and a gap can be generated between at least one of the first metal layer 4 and the second metal layer 6 and the ceramic substrate 2. At least one of the first metal layer 4 and the second metal layer 6 is brought into closer contact with the ceramic substrate 2 by the pressing, and the gap between at least one of the first metal layer 4 and the second metal layer 6 and the ceramic substrate 2 is reduced. This can suppress deterioration of the first wiring 3 and the second wiring 5 due to the influence of the external environment. Typically, sulfurization of the first wiring 3 and the second wiring 5 is suppressed.

When an assembly substrate including a plurality of ceramic substrates 2 aligned in the row direction and the column direction is used, the assembly substrate is cut after the formation of the metal layer so as to be separated into wiring substrates 1a as individual pieces. The cutting can be performed with, for example, a laser or a blade.

### Second Embodiment

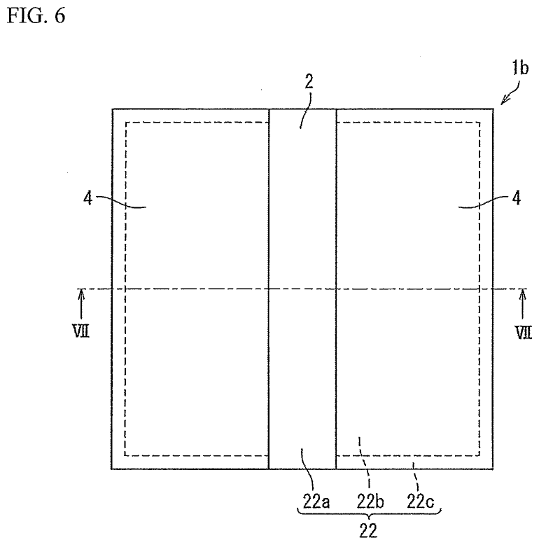

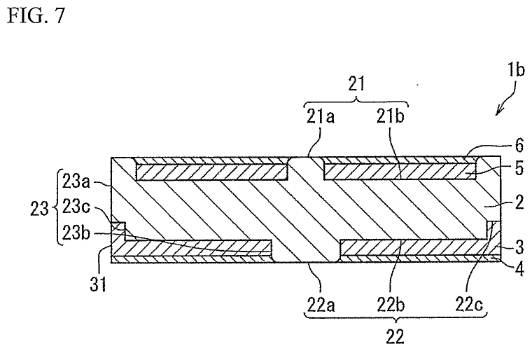

A wiring substrate 1b and a manufacturing method thereof according to a second embodiment are described with reference to FIGS. 6 and 7.

The wiring substrate 1b according to the second embodiment is different from the wiring substrate 1a according to the first embodiment in that the lateral surface 23 of the ceramic substrate 2 further includes a third lateral surface 23c between the first lateral surface 23a and the second lateral surface 23b, the lower surface 22 of the ceramic substrate 2 further includes a third lower surface 22c located inward from the second lower surface 22b, the second lower surface 22b is provided between the second lateral surface 23b and the third lateral surface 23c, the third lower surface 22c is continuous from the third lateral surface 23c, and the first wiring 3 is continuously disposed in contact with the second lateral surface 23b, the second lower surface 22b, the third lateral surface 23c, and the third lower surface 22c.

The lateral surface 31 of the first wiring 3 and the first lateral surface 23a of the ceramic substrate 2 are preferably flush with each other.

In the wiring substrate 1b, since the area of the first wiring 3 on the lateral surface is increased, a contact area of solder when the wiring substrate 1b is connected to another component, for example, a mounting substrate is increased, so that the adhesion and the thermal conductivity are increased.

A manufacturing method of the wiring substrate 1b according to the second embodiment is different from the manufacturing method of the wiring substrate 1a according to the first embodiment in that the manufacturing method of the wiring substrate 1b includes in (a) preparing the ceramic substrate, preparing the ceramic substrate 2 in which the third lateral surface 23c is further provided between the first lateral surface 23a and the second lateral surface 23b, the lower surface 22 further includes the third lower surface 22c located inward from the second lower surface 22b, the second lower surface 22b is provided between the second lateral surface 23b and the third lateral surface 23c, and the third lower surface 22c is continuous from the third lateral surface 23c, and in (b) forming the first conductive paste layer 41, forming the first conductive paste layer 41 such that it is continuously disposed in contact with the second lateral surface 23b, the second lower surface 22b, the third lateral surface 23c, and the third lower surface 22c.

### Third Embodiment

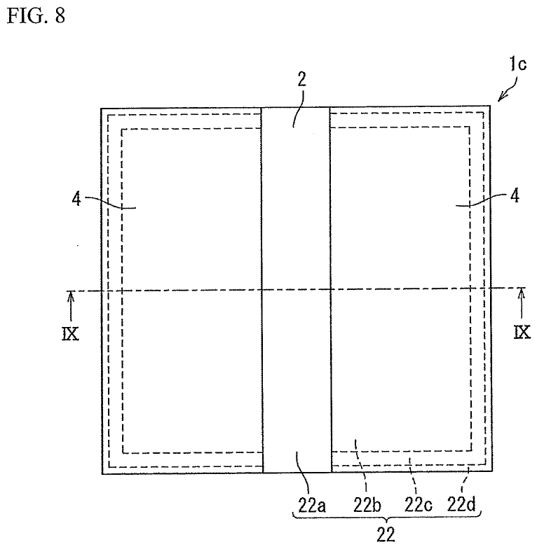

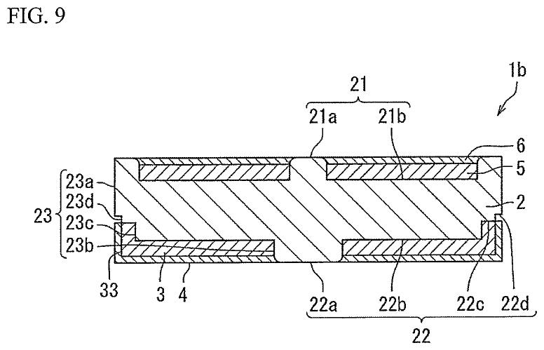

A wiring substrate 1c according to a third embodiment is described with reference to FIGS. 8 and 9.

The wiring substrate 1c according to the third embodiment is different from the wiring substrate 1b according to the second embodiment in that the lateral surface 23 of the ceramic substrate 2 further includes a fourth lateral surface 23d between the first lateral surface 23a and the third lateral surface 23c, the lower surface 22 of the ceramic substrate 2 further includes a fourth lower surface 22d located inward from the third lower surface 22c, the first wiring 3 is not disposed on the fourth lateral surface 23d and the fourth lower surface 22d, and the first metal layer 4 is also disposed on the lateral surface 33 of the first wiring 3. In the wiring substrate 1c, the first wiring 3 is continuously disposed in contact with the second lateral surface 23b, the second lower surface 22b, the third lateral surface 23c, and the third lower surface 22c.

By disposing the first metal layer 4 on the lateral surface 33 of the first wiring 3, solder wettability to the lateral surface of the wiring substrate is improved and heat dissipation is improved.

The lateral surface 33 of the first wiring 3 and the fourth lateral surface 23d of the ceramic substrate 2 are preferably flush with each other.

A manufacturing method of the wiring substrate 1c according to the third embodiment is different from the manufacturing method of the wiring substrate 1b according to the second embodiment in that in (a) preparing the ceramic substrate 2, the ceramic substrate 2 is prepared in which the fourth lateral surface 23d is further provided between the first lateral surface 23a and the third lateral surface 23c and the lower surface 22 further includes the fourth lower surface 22d located inward from the third lower surface 22c, in (b) forming the first conductive paste layer 41, the first conductive paste layer 41 is formed such that the first conductive paste is not disposed on the fourth lateral surface 23d and the fourth lower surface 22d, and in (e) forming the metal layer on the wiring, a half cut is made on the first wiring 3 to a depth reaching the ceramic substrate before the first metal layer 4 is formed and the first metal layer 4 is also disposed on a half cut portion.

### Fourth Embodiment

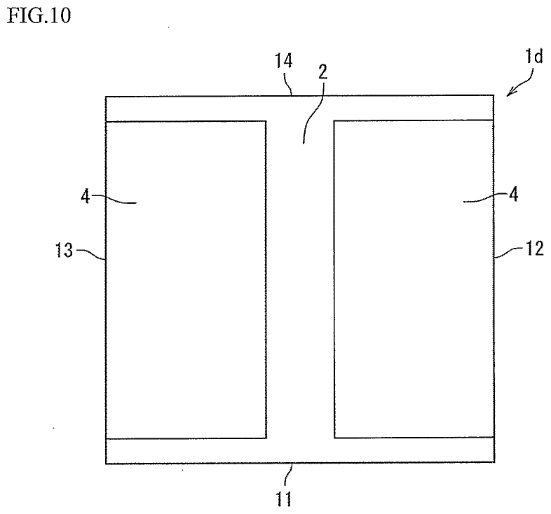

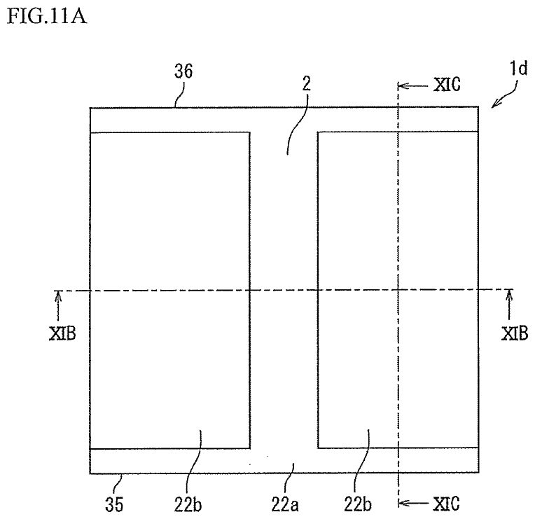

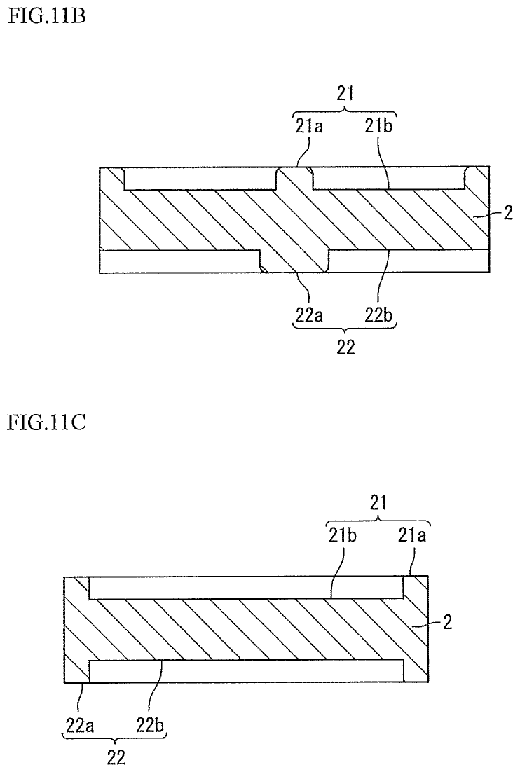

A wiring substrate 1d and a manufacturing method thereof according to a fourth embodiment are described with reference to FIG. 10 and FIGS. 11A to 11C. FIG. 10 is a schematic bottom view of the wiring substrate 1d.

The wiring substrate 1d according to the fourth embodiment has a rectangular shape in top view and is different from the wiring substrate 1a according to the first embodiment in that lateral surfaces of the wiring substrate 1d include the front surface 11, the right lateral surface 12 and the left lateral surface 13 adjacent to the front surface 11, and the back surface 14 opposite to the front surface 11 and adjacent to the right lateral surface 12 and the left lateral surface 13, and the first wiring 3 is present on the right lateral surface 12 and the left lateral surface 13 and is not present on the front surface 11 and the back surface 14.

A manufacturing method of the wiring substrate 1d according to the fourth embodiment is different from the manufacturing method of the wiring substrate 1a according to the first embodiment in that in (a) preparing the ceramic substrate 2, the ceramic substrate 2 in which the first lower surface 22a is further present along a front surface 35 and a back surface 36 is prepared.

### First Modified Example

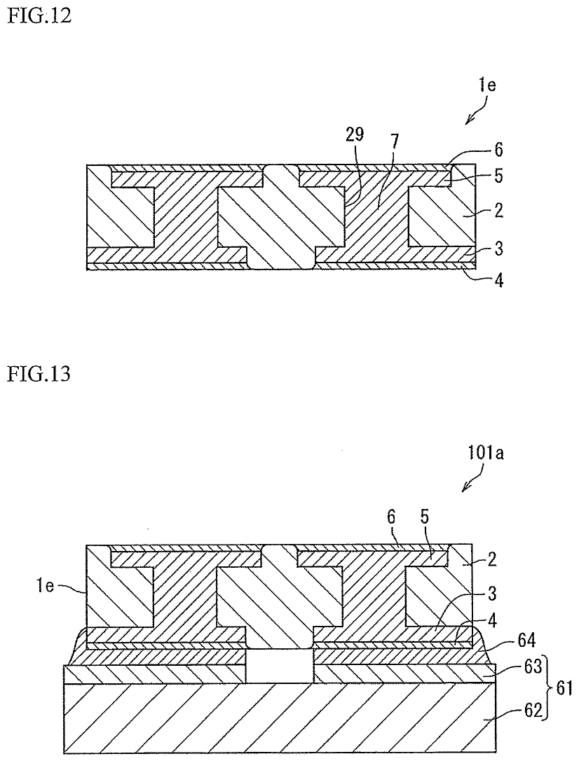

FIG. 12 is a schematic cross-sectional view of a wiring substrate 1e according to a first modified example. As illustrated in FIG. 12, the wiring substrate 1e according to the first modified example is different from the wiring substrate 1a according to the first embodiment in that the ceramic substrate 2 has a through hole 29 connecting the second upper surface 21b and the second lower surface 22b and the first wiring 3 and the second wiring 5 are connected by a conductor 7 disposed in the through hole 29. The aspect of the first modified example can be applied to any of the first to fourth embodiments.

A manufacturing method of the wiring substrate 1e according to the first modified example is different from the manufacturing method of the wiring substrate 1a according to the first embodiment in that in (a) preparing the ceramic substrate 2, the ceramic substrate 2 further having the through hole 29 connecting the second lower surface 22b and the second upper surface 21b is prepared, and in (b) forming the first conductive paste layer 41 and the second conductive paste layer 42, a third conductive paste layer connecting the first conductive paste layer 41 and the second conductive paste layer 42 is further formed.

### Fifth Embodiment

A composite substrate 101a according to a fifth embodiment is described with reference to FIG. 13.

The composite substrate 101a includes a first component 61 and a connection member 64 that electrically connects the first wiring 3 of the wiring substrate 1e and the first component 61.

The first component 61 is typically a mounting substrate. The mounting substrate used as the first component 61 includes a substrate 62 and a wiring 63. The connection member 64 electrically connects the wiring 63 of the mounting substrate and the first wiring 3 of the wiring substrate 1e. In the composite substrate 101a, the connection member 64 is disposed in contact with both the first metal layer 4 and the lateral surface of the first wiring 3. By disposing the connection member 64 up to the lateral surface of the first wiring 3, a contact area between the connection member 64 and the wiring substrate 1e is increased, and the connection strength and the thermal conductivity are improved. When the first metal layer 4 is not present, the connection member 64 is disposed in contact with both the lower surface of the first wiring 3 and the lateral surface of the first wiring 3.

The connection member 64 can be a solder, a metal paste, or a conductive adhesive, and is preferably a solder.

### Sixth Embodiment

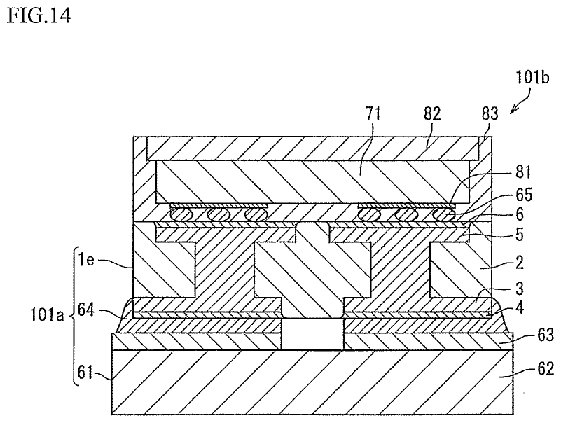

A composite substrate 101b according to a sixth embodiment is described with reference to FIG. 14.

The composite substrate 101b according to the sixth embodiment is different from the composite substrate 101a according to the fifth embodiment in that the composite substrate 101b further includes a second component 71 and connection members 65 electrically connect the second metal layer 6 and the second component 71. When the second metal layer 6 is not present, the connection members 65 electrically connect the upper surface of the second wiring 5 and the second component 71.

The second component 71 can be a light-emitting element. The light-emitting element used as the second component 71 is a member that is supplied with power and emits light. A shape of the light-emitting element in plan view is, for example, rectangular. The light-emitting element includes a semiconductor layered body. Here, a light-transmissive substrate made of sapphire, gallium nitride, or the like is disposed on an upper surface side of the semiconductor layered body. A pair of element electrodes 81 are provided on a lower surface side of the semiconductor layered body. For the semiconductor layered body, a predetermined composition can be used in accordance with a desired emission wavelength. For example, a nitride semiconductor (InₓAl_{y}Ga_{1-x-y}N, 0≤X, 0≤Y, X+Y≤1) or GaP, which can emit blue or green light, or GaAlAs or AlInGaP, which can emit red light, can be used. The size and the shape of the light-emitting element can be appropriately selected in accordance with the purpose of use.

The pair of element electrodes 81 each have a rectangular shape in plan view, for example, and are exposed on a lower surface of the light-emitting element. The element electrodes 81 can be formed of, for example, a single-layer film or a layered film of a metal such as gold, platinum, palladium, rhodium, nickel, tungsten, molybdenum, chromium, or titanium, or an alloy thereof.

The element electrodes 81 are connected to the second metal layer 6 of the wiring substrate 1e via the connection members 65.

### Light-Transmissive Member

A light-transmissive member 82 is a member that protects an upper surface of the light-emitting element used as the second component 71 and is located on a light extraction surface of the light-emitting element. The light-transmissive member 82 has a rectangular shape, for example, and has a size and shape including the light-emitting element in plan view. The light-transmissive member 82 can have the same size and shape as the light-emitting element in plan view.

For example, the light-transmissive member 82 is made of a light-transmissive resin material, and an epoxy resin, a silicone resin, a resin in which an epoxy resin and a silicone resin are mixed, or the like can be used. The light-transmissive member 82 can contain a phosphor, and for example, when the light-transmissive member 82 contains a phosphor that absorbs blue light from the light-emitting element and emits yellow light, white light can be emitted. The light-transmissive member 82 can contain a plurality of types of phosphors. For example, when the light-transmissive member 82 contains a phosphor that absorbs blue light from the light-emitting element and emits green light and a phosphor that emits red light, white light can also be emitted.

The light-transmissive member 82 can further contain a light-emitting material such as a phosphor or quantum dots. Examples of such a phosphor include yttrium-aluminum (gallium-doped) garnet activated with cerium, nitrogen-containing calcium (strontium) aluminosilicate activated with europium, potassium fluorosilicate activated with manganese, and a β-SiA1ON phosphor. Specific examples of the phosphor include an yttrium aluminum garnet phosphor (for example, (Y,Gd)₃(Al,Ga)₅O₁₂:Ce), a lutetium aluminum garnet phosphor (for example, Lu₃(Al,Ga)₅O₁₂:Ce), a terbium aluminum garnet phosphor (for example, Tb₃(Al,Ga)₅O₁₂:Ce), a CCA phosphor (for example, Ca₁₀(PO₄)₆Cl₂:Eu), an SAE phosphor (for example, Sr₄Al₁₄O₂₅:Eu), a chlorosilicate phosphor (for example, Ca₈MgSi₄O₁₆Cl₂:Eu), a silicate phosphor (for example, (Ba,Sr,Ca,Mg)₂SiO₄:Eu), oxynitride phosphors such as a β-SiAlON phosphor (for example, (Si,Al)₃(O,N)₄:Eu) and an α-SiAlON phosphor (for example, Ca(Si,Al)₁₂(O,N)₁₆:Eu), nitride phosphors such as an LSN phosphor (for example, (La,Y)₃Si₆N₁₁:Ce), a BSESN phosphor (for example, (Ba,Sr)₂Si₅N₈:Eu), an SLA phosphor (for example, SrLiAl₃N₄:Eu), a CASN phosphor (for example, CaAlSiN₃:Eu), and an SCASN phosphor (for example, (Sr,Ca)AlSiN₃:Eu), fluoride phosphors such as a KSF phosphor (for example, K₂SiF₆:Mn), a KSAF phosphor (for example, K₂(Si₁₋ₓAlₓ)F₆₋ₓ:Mn, where x satisfies 0<x<1), and an MGF phosphor (for example, 3.5MgO·0.5MgF₂·GeO₂:Mn), and the like. Examples of the quantum dots include quantum dots having a perovskite structure (for example, (Cs,FA,MA)(Pb,Sn)(F,Cl,Br,I)₃, where FA represents formamidinium and MA represents methylammonium), II-VI group quantum dots (for example, CdSe), III-V group quantum dots (for example, InP), quantum dots having a chalcopyrite structure (for example, (Ag,Cu)(In,Ga)(S,Se)₂), and the like.

### Covering Member

A covering member 83 is a member that is disposed on an upper surface of the wiring substrate 1e and covers and protects lateral surfaces of the light-emitting element used as the second component 71 and the light-transmissive member 82. The covering member 83 is disposed with an upper surface of the light-transmissive member 82 exposed. The covering member 83 also covers lateral surfaces of the element electrodes 81 and the connection members 65 by entering between the light-emitting element and the wiring substrate 1e.

The covering member 83 can be formed of a resin having any of light reflectivity, light transmissivity, a light blocking property, and the like, or a resin containing a light reflective substance or a light blocking substance in any of these resins having light transmissivity. The covering member 83 preferably has at least light reflectivity and a light blocking property. Examples of the resin include a resin containing one or more of a silicone resin, a modified silicone resin, an epoxy resin, a modified epoxy resin, and an acrylic resin, and a hybrid resin. Examples of the light reflective substance include titanium oxide, silicon oxide, zirconium oxide, potassium titanate, aluminum oxide, aluminum nitride, boron nitride, and mullite. The covering member 83 can contain a phosphor, a diffusing material, a colorant, and the like.

1. A wiring substrate comprising:
a ceramic substrate having an upper surface, a lower surface opposite to the upper surface, and a lateral surface between the upper surface and the lower surface, the lower surface comprising a first lower surface located on a first outermost side of the ceramic substrate and a second lower surface located inward from the first lower surface, the lateral surface comprising a first lateral surface located on a second outermost side of the ceramic substrate and a second lateral surface located inward from the first lateral surface; and
a first wiring having a thickness of 80% or more of a height from the second lower surface to the first lower surface, the first wiring being disposed in contact with the second lower surface and the second lateral surface, wherein
a lateral surface of the first wiring is exposed from the first lateral surface of the ceramic substrate, and
a main surface of a lower surface of the first wiring is substantially parallel to the second lower surface, the main surface being disposed inward from the first lower surface, the main surface being 50% or more of a surface area of the lower surface of the first wiring.

2. The wiring substrate according to claim 1, wherein
the upper surface of the ceramic substrate comprises a first upper surface and a second upper surface located inward from the first upper surface, and
the wiring substrate further comprises a second wiring having a thickness of 80% or more of a height from the second upper surface to the first upper surface, the second wiring being disposed in contact with the second upper surface.

3. The wiring substrate according to claim 1, wherein
the lateral surface of the ceramic substrate further comprises a third lateral surface between the first lateral surface and the second lateral surface,
the lower surface of the ceramic substrate further comprises a third lower surface located inward from the second lower surface,
the second lower surface is provided between the second lateral surface and the third lateral surface,
the third lower surface is continuous from the third lateral surface, and
the first wiring is continuously disposed in contact with the second lateral surface, the second lower surface, the third lateral surface, and the third lower surface.

4. The wiring substrate according to claim 1, wherein the main surface of the lower surface of the first wiring is located 0.4 μm or more and 5.0 μm or less inward from the first lower surface.

5. The wiring substrate according to claim 3, wherein
the lateral surface of the ceramic substrate further comprises a fourth lateral surface between the first lateral surface and the third lateral surface,
the lower surface of the ceramic substrate further comprises a fourth lower surface located inward from the third lower surface, and
the first wiring is not disposed on the fourth lateral surface and the fourth lower surface.

6. The wiring substrate according to claim 1, further comprising a first metal layer disposed on the lower surface of the first wiring, wherein
a surface of the first metal layer and the first lower surface are flush with each other.

7. The wiring substrate according to claim 2, further comprising a second metal layer disposed on an upper surface of the second wiring.

8. The wiring substrate according to claim 1, wherein the first wiring and the first lower surface are spaced apart from each other.

9. The wiring substrate according to claim 2, wherein the second wiring and the first upper surface are spaced apart from each other.

10. The wiring substrate according to claim 1, wherein
the wiring substrate has a rectangular shape in top view,
lateral surfaces of the wiring substrate comprise a front surface, a right lateral surface, a left lateral surface adjacent to the front surface, and a back surface opposite to the front surface, the back surface being adjacent to the right lateral surface and the left lateral surface, and
the first wiring is present on the front surface, the right lateral surface, the left lateral surface, and the back surface.

11. The wiring substrate according to claim 1, wherein
the wiring substrate has a rectangular shape in top view,
lateral surfaces of the wiring substrate comprise a front surface, a right lateral surface, a left lateral surface adjacent to the front surface, and a back surface opposite to the front surface, the back surface being adjacent to the right lateral surface and the left lateral surface, and
the first wiring is present on the right lateral surface and the left lateral surface, and the first wiring is not present on the front surface and the back surface.

12. The wiring substrate according to claim 6, wherein
in cross-sectional view in a thickness direction of the ceramic substrate,
a first corner portion defined by the first lower surface and the second lateral surface is rounded, and
the first metal layer covers the first corner portion.

13. The wiring substrate according to claim 7, wherein
in cross-sectional view in a thickness direction of the ceramic substrate,
a second corner portion defined by the first upper surface and a fifth lateral surface connecting the first upper surface and the second upper surface is rounded, and
the second metal layer covers the second corner portion.

14. A composite substrate comprising:
the wiring substrate according to claim 1;
a first component; and
a connection member that electrically connects the first wiring of the wiring substrate and the first component.

15. The composite substrate according to claim 14, wherein
the wiring substrate further comprises a first metal layer disposed on the lower surface of the first wiring, and
the connection member is disposed in contact with:
the lower surface of the first wiring or the first metal layer; and
the lateral surface of the first wiring.

16. The composite substrate according to claim 15, wherein
the wiring substrate further comprises a second metal layer disposed on an upper surface of a second wiring,
the composite substrate further comprises a second component, and
the connection member electrically connects the upper surface of the second wiring or the second metal layer and the second component.

17. A manufacturing method of a wiring substrate, comprising:
preparing a ceramic substrate comprising an upper surface, a lower surface opposite to the upper surface, and a lateral surface between the upper surface and the lower surface, the lower surface comprising a first lower surface located on a first outermost side of the ceramic substrate and a second lower surface located inward from the first lower surface, the lateral surface comprising a first lateral surface located on a second outermost side of the ceramic substrate and a second lateral surface located inward from the first lateral surface;
forming a first conductive paste layer by disposing a first conductive paste on the second lower surface;
forming a first wiring intermediate by firing the first conductive paste layer; and
forming a first wiring such that a main surface of a lower surface of the first wiring is substantially parallel to the second lower surface, the main surface being 50% or more of a surface area of the lower surface of the first wiring, the first wiring being disposed inward from the first lower surface, by polishing or grinding the first wiring intermediate, wherein
in the forming of the first wiring, the first wiring has a thickness of 80% or more of a height from the second lower surface to the first lower surface, the first wiring being disposed in contact with the second lower surface and the second lateral surface, and a lateral surface of the first wiring is exposed from the first lateral surface of the ceramic substrate.

18. The manufacturing method of a wiring substrate, according to claim 17, wherein
in the preparing the ceramic substrate, the ceramic substrate is further provided, on the upper surface of the ceramic substrate, with a first upper surface and a second upper surface located inward from the first upper surface, and
the manufacturing method further comprises:
after the preparing of the ceramic substrate, forming a second conductive paste layer by disposing a second conductive paste on the second upper surface; and
in the forming of the first wiring intermediate, forming a second wiring intermediate by firing the second conductive paste layer.

19. The manufacturing method of a wiring substrate, according to claim 18, further comprising:
after the forming of the second wiring intermediate, forming a second wiring having an upper surface located inward from the first upper surface, by polishing or grinding the second wiring intermediate, wherein
in the forming of the second wiring, the second wiring has a thickness of 80% or more of a height from the second upper surface to the first upper surface, the second wiring being disposed in contact with the second upper surface.

20. The manufacturing method of a wiring substrate, according to claim 17, wherein
in the preparing of the ceramic substrate, the ceramic substrate is prepared in which a third lateral surface is further provided between the first lateral surface and the second lateral surface, the lower surface of the ceramic substrate further comprises a third lower surface located inward from the second lower surface, the second lower surface is provided between the second lateral surface and the third lateral surface, and the third lower surface is continuous from the third lateral surface, and
in the forming of the first conductive paste layer, forming the first conductive paste layer such that the first conductive paste layer is continuously disposed in contact with the second lateral surface, the second lower surface, the third lateral surface, and the third lower surface.

21. The manufacturing method of a wiring substrate, according to claim 17, wherein, in the forming of the first wiring, the first wiring intermediate is polished or ground such that the main surface of the lower surface of the first wiring is located at least 0.4 μm or more inward from the first lower surface.

22. The manufacturing method of a wiring substrate, according to claim 20, wherein
in the preparing of the ceramic substrate, the ceramic substrate is prepared in which a fourth lateral surface is further provided between the first lateral surface and the third lateral surface, the lower surface of the ceramic substrate further comprises a fourth lower surface located inward from the third lower surface, and
in the forming of the first conductive paste layer, the first conductive paste layer is formed such that the first conductive paste is not disposed on the fourth lateral surface and the fourth lower surface.

23. The manufacturing method of a wiring substrate, according to claim 17, further comprising:
after the forming of the first wiring, forming a first metal layer on the lower surface of the first wiring, wherein
in the forming of the first metal layer, the first metal layer is formed such that a surface of the first metal layer and the first lower surface are flush with each other.

24. The manufacturing method of a wiring substrate, according to claim 19, further comprising, after the forming of the second wiring, forming a second metal layer on an upper surface of the second wiring.

25. The manufacturing method of a wiring substrate, according to claim 24, wherein, in the forming of at least one of the first metal layer and the second metal layer, at least one of the first metal layer and the second metal layer is formed by plating.

26. The manufacturing method of a wiring substrate, according to claim 25, wherein, in the forming of at least one of the first metal layer and the second metal layer, an edge portion of at least one of the first metal layer and the second metal layer is further pressed.
